(19) United States
(12) Patent Application Publication
(10) Pub. No.: US 2012/0097238 A1
(43) Pub. Date: Apr. 26, 2012

(54) GRAPHENE-BASED SOLAR CELL

(76) Inventor: Akinbode I. Isaacs-Sodeye, Chandler, AZ (US)

(21) Appl. No.: 13/281,336

(22) Filed: Oct. 25, 2011

Related U.S. Application Data
(60) Provisional application No. 61/406,166, filed on Oct. 25, 2010.

(51) Int. Cl. H01L 51/46; H01L 31/18; H01L 31/0232; H01L 31/0224; B82Y 40/00

(52) U.S. Cl. 136/256; 136/252; 136/259; 136/263; 438/57; 977/734; 257/E31.001

(57) ABSTRACT

A solar cell includes a transparent upper electrode for conducting electrons and for allowing incoming photons of light to pass therethrough. An exciton trapping region is disposed proximate the upper electrode, and includes graphene and an exciton trapping dye. The trapping dye traps captured excitons, and the graphene rapidly conducts freed electrons therefrom to the upper electrode. A pigment layer, in close proximity to the exciton trapping region, includes one or more pigment dyes that absorb light photons and emit excitons for transmission to the trapping dye. Excitons emitted by a first pigment dye can further trigger emission of excitons by a second pigment dye. A backing electrode is electrically coupled to the pigment layer via an anionic polyelectrolyte for transporting electrons to the pigment layer to replenish electrons conducted by the transparent upper electrode.

### CROSS REFERENCE TO RELATED APPLICATIONS

This application claims the benefit of the earlier filing date of U.S. provisional patent application No. 61/406,166, entitled “Graphene-Based Solar Cell”, filed on Oct. 25, 2010, by the same inventor named herein, pursuant to 35 USC §119(e).

### FIELD OF THE INVENTION

The present invention relates generally to solar cells for generating electricity, and more particularly, to a highly-efficient solar cell using graphene and one or more dyes.

### DESCRIPTION OF THE RELATED ART

Solar generated electricity originated with the unintentional discovery of the capability of silicon and selenium to convert the sun's energy to a moving current. In the late 1870s, British engineer, Willoughby Smith, while trying to use selenium to measure resistance of undersea cables, discovered that the erratic measurements he obtained were due to the varying amounts of light hitting the metal during the experiments. This discovery spurred W. G Adams and R. E Day to perform further experiments that proved that light could be repeatably used to generate a current in selenium. Within a few years, American inventor C. E. Fritts produced a solar battery consisting of a sheet of selenium sandwiched between a metal backing and a transparent gold leaf film. At this early stage, solar cells converted no more than 1% of the sun's energy into electricity.

The first generation of practical solar cells took advantage of light-dependent conductivity of doped silicon, using silicon wafers already being produced to make transistors. Scientists working on silicon rectifiers at Bell Labs in 1954 observed that rectifiers could be made more efficient by adding certain impurities to silicon. However, their measurements were erratic, and it was later realized that the values measured depended on the amount of light incident on the device. This work by developers Calvin Fuller, Gerald Pearson, and Daryl Chapin gave birth to the silicon-wafer-based photovoltaics industry, which is the still the dominant form of commercially-available solar energy conversion devices. Nonetheless, silicon wafer based solar cells do have certain disadvantages, including relatively high cost, delicate processing steps, and reduced efficiency when operating at higher temperatures.

Spurned by the success of silicon wafer solar cell technology, many other kinds of semiconductor materials have been developed and applied to solar cell technology since the 1970s, including CIS, CdTe, InP, GaAs, as well as polycrystalline and amorphous silicon. By the early 1980s, solar cells were developed using much less expensive polycrystalline silicon deposited as thin films onto glass substrates. The elimination of the need for silicon wafers, and the reduction in the quantity of silicon needed as a result of thinner films, achieved significant cost reductions. Also, polysilicon could be deposited directly onto large-area glass sheets, increasing manufacturing efficiencies. However, while the use of polysilicon reduced material costs, polysilicon has a lower conversion efficiency than single crystalline silicon wafers. Moreover, the deposition of polycrystalline silicon requires high vacuum processes, which are themselves relatively expensive.

The emerging third generation of solar cells combine the use of less expensive inorganic and organic photovoltaic materials with faster process technologies, such as roll-to-roll printing on conductive foil substrates under ambient conditions. One major example of such systems are organic dye-sensitized solar cells. Such devices employ the light absorbing properties of organic dyes, and the electron conductivity of semiconductor particles, to form a photoinduced energy conversion cycle, similar to photosynthetic plants. A dye-sensitized solar cell is a class of low-cost thin film solar cells. A semiconductor is formed between a photo-sensitized anode and an electrolyte, forming a photoelectrochemical system. This cell was invented by Michael Grätzel and Brian O'Regan at the École Polytechnique Fédérale de Lausanne in 1991, and is also known as a Grätzel cell.

Grätzer's cell is composed of a porous layer of titanium dioxide nanoparticles covered with a molecular dye that absorbs sunlight, like the chlorophyll in green leaves. A transparent anode is made by depositing an electrically-conductive layer of fluoride-doped tin dioxide (SnO2:F) on a glass plate. A thin layer of titanium dioxide (TiO2) is also deposited upon the anode, which forms into a highly porous structure with an extremely high surface area. Pure TiO2 only absorbs a small fraction of the solar photons (i.e., those in the ultra-violet range). The anode plate is then immersed in a mixture of a photosensitive ruthenium-polypyridine dye and a solvent. A thin layer of the dye is left covalently bonded to the surface of the TiO2.

Sunlight passes through the transparent anode into the dye layer; the dye layer absorbs photons and thereby excites electrons; the excited electrons then flow into the titanium dioxide. The electrons flow toward the conductive layer of the transparent anode where they are collected for powering a load. After flowing through the external circuit, they are re-introduced into the cell on a metal cathode. An electrolyte is provided between the anode and the cathode, and the electrolyte then transports the electrons back to the dye molecules.

Dye-sensitized solar cells produce particles of matter called “excitons”. An exciton is a bound state of an electron and a “hole” which are attracted to each other by electrostatic Coulomb forces. An exciton is an electrically neutral quasiparticle that exists in semiconductors and other materials. The exciton is regarded as an elementary excitation of matter that can transport energy without transporting net electric charge. An exciton forms when a photon is absorbed by a semiconductor. This excites an electron from the valence band into the conduction band. In turn, this leaves behind a localized positively-charged hole. The electron in the conduction band is then attracted to this localized hole by the Coulomb force.

While the Grätzel cell formed its transparent anode using a layer of tin oxide, it has more recently been proposed that graphene may be used to form a transparent conductive anode for dye-sensitized solar cells. For example, in Wu, et al., “Organic solar cells with solution-processed graphene transparent electrodes”, Applied Physics Letters 92, 263302 (2008), the authors describe solution-processed graphene thin films, deposited upon quartz substrates, that serve as transparent conductive anodes for organic photovoltaic cells. Graphene is a planar sheet of sp2-bonded carbon atoms, only a few atoms thick, that are densely packed in a honeycomb crystal lattice. Graphene is highly-conductive and highly-transparent.

Solar conversion efficiency for known dye-sensitized solar cells ranges from about 6%-11%. While known dye-sensitized solar cells can be made less expensively than older silicon solar cells, they are not nearly as efficient as older silicon solar cells. Applicant has theorized that perhaps this lack of efficiency is due to inefficient collection of excitons emitted when photons strike the aforementioned dye layer. If these excitons are not trapped quickly, and the excited electrons rapidly conducted away, then the potential electrical current that they represent is lost.

Accordingly, it is an object of the present invention to provide a relatively inexpensive (i.e., less than $0.75/watt) photovoltaic cell with a starting sunlight conversion efficiency approaching 18% or more.

It is another object of the present invention to provide such a photovoltaic cell that does not require a semiconductor substrate.

Still another object of the present invention is to provide such a photovoltaic cell that is relatively easy to manufacture.

A further object of the present invention is to provide such a photovoltaic cell adapted to capture a relatively large portion of the impinging light spectra (visible or not) to increase the efficiency of converting light energy into electricity.

It is yet another object of the present invention to provide such a solar cell which more effectively traps excitonic energy.

Still another object of the present invention is to provide such a solar cell that ensures rapid electron transfer, and a charge-separated state sufficiently low in energy, to prevent back transfer of excitation energy.

A further object of the present invention is to provide such a solar cell which minimizes recombination losses by ensuring fast forward reaction rates, along with fast conduction of trapped electrons, to avoid a trap-limited electron transfer.

A still further object of the present invention is to provide such a solar cell having a well defined structural arrangement of donor and acceptor pigments in order to maximize efficiency of electron transfer and charge separation.

Yet another object of the present invention is to provide such a solar cell having an appropriate distance between the primary electron donor and the final electron acceptor before free electrons are passed into a load electrical circuit, in order to maximize charge separation, avoid recombination, and maximize light to energy conversion efficiency.

These and other object of the present invention will become more apparent to those skilled in the art as the description of the present invention proceeds.

### SUMMARY OF THE INVENTION

Briefly described, and in accordance with a preferred embodiment thereof, the present invention is a solar cell which includes a transparent upper electrode for conducting electrons and for allowing incoming photons of light to pass therethrough. An exciton trapping region, preferably formed as a layer of material, is disposed proximate to the transparent upper electrode, and includes graphene and a first dye. As used herein, the term “exciton trapping region” includes without limitation, an excition trapping layer of material. The first dye of the exciton trapping layer serves trap captured excitons, and the graphene rapidly conducts freed electrons from the trapped excitons to the transparent electrode for supply to a load circuit. The first dye included in the exciton trapping layer is preferably formed of squaraine dyes and/or croconylium dyes.

A pigment layer is provided in close proximity to the exciton trapping layer; this pigment layer includes at least a second dye different from the first dye included in the exciton trapping layer. The second dye of the pigment layer absorbs photons of light within a first wavelength spectrum and emits excitons in response thereto. Ideally, the first and second dyes work hand-in-hand, whereby the first dye in the exciton trapping layer traps excitons that are within a predetermined exciton wavelength spectrum, while the second dye in the pigment layer emits excitons that are within the predetermined exciton wavelength spectrum.

The above-mentioned pigment layer preferably includes at least two distinct patches of dyes, namely, a first patch that includes a second dye different from the first dye included in the exciton trapping layer, and a second patch that includes a third dye different from the first and second dyes. The second dye in the first patch of the pigment layer absorbs photons of light within one portion of a first wavelength spectrum, and emits excitons in response thereto. The third dye in the second patch of the pigment layer absorbs photons of light within a second portion of the first wavelength spectrum, and also emits excitons in response thereto. Preferably, these second and third dyes are selected from a group of pigments that includes porphyrin pigments, carotene pigments, and phenylenediamines. The first and second patches of dyes in the pigment layer are preferably separated from each other by a space. Ideally, the aforementioned space is filled with a combination of graphene and the first dye to more effectively trap emitted excitons.

Significant numbers of the excitons emitted by the second dye in the first patch of the pigment layer are directly trapped by the first dye in the exciton trapping layer. Some excitons emitted by the second dye in the first patch of the pigment layer are donated to, and accepted by, the third dye in the second patch of the pigment layer. In turn, the third dye emits excitons that are then trapped by the first dye in the exciton trapping layer. If desired, the pigment layer may also include a photoactive semiconductor polymer, e.g., pentacene. The aforementioned exciton trapping layer, including its exciton trapping dye, and its graphene atoms, and the light-absorbing pigment layer, may be joined together, if desired, as by covalent bonding and/or by physical contact or absorption, to form a single combined layer of material. In addition, silicone moieties may be provided along with the exciton trapping layer and pigment layer to form a rubbery network.

The solar cell also includes a backing electrode that is electrically coupled to the pigment layer for transporting electrons to the pigment layer to replenish electrons conducted by the transparent upper electrode. This backing electrode is preferably formed as either a metal sheet or a metalized polymer sheet. In the preferred embodiment of the invention, an anionic polyelectrolyte is included between the backing electrode and the pigment layer to transfer electrons from the backing electrode to the pigment layer to replace those freed electrons conducted away by the transparent upper electrode. If desired, the anionic polyelectrolyte may be rendered acidic to provide sacrificial electron donors. The anionic polyelectrolyte may include electron carriers such as quaternary ammonium, barium halides, calcium halides, salts, ionic liquids, and imidazoles. In the preferred embodiment of the present invention, the anionic polyelectrolyte includes polyphosphazene in liquid or gel form.

In the preferred embodiment, the solar cell includes a light concentrating cover sheet to focus incoming solar light through the transparent upper electrode and into the pigment layer. Preferably, this cover sheet is made of a transparent polymer or glass; as used herein, the term “polymer” should be understood to include, without limitation, a polymer gel. The transparent polymer or glass cover sheet has a transparent, electrically-conductive layer formed upon its lower surface adjacent the exciton trapping layer. This transparent electrically conductive layer is preferably formed of a thin film of indium tungsten oxide (ITO).

The upper surface of the transparent cover sheet (i.e., the surface directed toward a source of light) may include at least one lens to focus incoming light downwardly through the transparent sheet toward the pigment layer. For example, the upper surface of the transparent cover sheet may incorporate a Fresnel lens to intercept and transmit incident light from a wide array of angles toward the pigment layer. In this case, the transparent cover sheet is a plastic Fresnel lens sheet.

To summarize the method of operation, sunlight (or other forms of illumination) strike the transparent upper electrode. The transparent upper electrode, if provided as a light concentrating sheet, gathers incident light over a wide angle and focuses the light onto the dye(s) in the pigment layer below. Photons from the light excite the dye(s) in the pigment layer; the pigment layer may include two or more different types of dyes each having different spectral absorption ranges, preferably maximizing energy absorption from the whole light spectrum (from visible to near infrared). The dye(s) in the pigment layer transmit excitons to the organic trapping dye in the exciton trapping layer, and/or to adjacent dyes within the pigment layer. In the latter case, a “donor” dye in the pigment layer transmits an exciton to an “acceptor” dye in the pigment layer. In order to maximize transmission of excitons from the donor dye to the acceptor dye, the emission spectra of the donor dye should overlap the absorption spectra of the acceptor dye. The acceptor dye can then emit additional excitons that are trapped by the dye in the exciton trapping layer.

Electron transfer to the exciton trapping dye occurs via a redox potential gradient from the dyes in the pigment layer to the exciton trapping dye, ensuring that the exciton trapping dye can oxidize the dyes in the pigment layer. Electrons are freed from the trapped excitons and transmitted to the attached graphene atoms. Graphene is highly-conductive, and rapidly conducts the freed electrons to the transparent electrode (anode) on the underside of the light concentrating sheet cover, and into the direct current circuit.

To replenish electrons conducted away by the anode (and to close the electrical load circuit), electrons are returned through the bottom electrode (or cathode), and adsorbed into the anionic polyelectrolyte layer, which transports excess electrons to the photon-collecting pigment layers, thus filling the “holes” created by the oxidizing of the pigments. In essence, the anionic polyelectrolyte reduces the dyes in the pigment layer, thus completing the circuit. The electron transfer may be facilitated by providing an acidic environment in parts of the cell.

### BRIEF DESCRIPTION OF THE DRAWINGS

FIG. 1 is an exploded perspective view of a five-layer, graphene-based solar cell in accordance with a preferred embodiment of the present invention.

FIG. 2 is a functional process diagram illustrating schematically the functions performed by the components of the solar cell.

FIG. 3 is a cross-sectional view of a transparent upper electrode including a light concentrating cover sheet, in the form of a thin-film Fresnel lens, to focus incoming light toward one or more dyes in an underlying pigment layer.

FIG. 4 is a perspective view of the backing electrode (cathode) incorporating a honeycombed conductive network.

### DETAILED DESCRIPTION OF THE PREFERRED EMBODIMENT

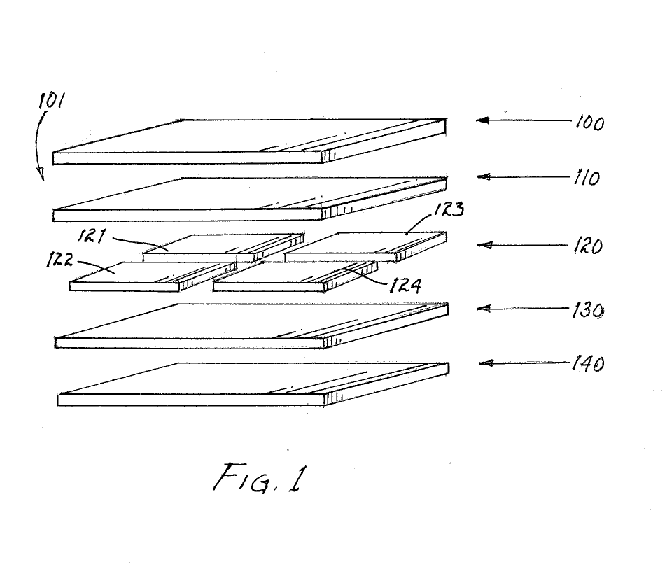

Referring to FIG. 1, a solar cell structure is shown in exploded form and is designated generally by reference numeral 101. Solar cell 101 includes an upper electrode (or anode) and light concentrator layer 100. Referring briefly to FIG. 3, upper electrode 100 is formed by depositing a transparent conductive layer 300 on the underside 302 of a transparent top sheet 304 made of a polymer or glass. Once again, such a polymer material may be in the form of a polymer gel. Top sheet 304 preferably forms a light concentrating member; as shown in FIG. 3, the upper surface 306 of top sheet 304 may incorporate a Fresnel to focus incoming light rays 308 and 310, coming from a variety of angles, downwardly, as parallel light rays 312 and 314, respectively, through upper electrode 100. An electrically conductive thin film, such as indium tungsten oxide (ITO), may be used to form transparent conductive layer 300 on the underside 302 of a transparent top sheet 304

As noted above, light concentrating sheet 304 of upper electrode 100 has an uppermost surface structure 306 forming one or more Fresnel lenses for concentrating incoming light onto underlying pigment layers 120. The upper surface 306 of such light concentrating sheet 304 preferably has a patterned geometry to intercept and transmit incident light from a wide array of angles. The light concentrating glass or polymer sheet is made from a material that maintains its clarity and transparency over the useful life of solar cell 101. Suitable plastic Fresnel lens sheets are commercially available from, for example, Anchor Optics of Barrington, N.J., and Nihon Tokushu Kogaku Jushi Co., Ltd. (NTKJ) of Tokyo, Japan.

As shown in FIG. 1, exciton trapping layer 110 is disposed immediately below transparent electrode 100. Exciton trapping layer includes both a thin layer of graphene and one or more exiton trapping dyes attached thereto. The exciton trapping dyes serve to trap excitons produced when photons strike pigment mats, or patches, formed therebelow. The exciton trapping dyes in layer 110 also transmit electrons from such trapping dyes to the graphene sheet within layer 110 (and on to transparent electrode 100) by redox gradient-based conductivity. The exciton trapping function is carried out by electron-withdrawing photoactive molecules, preferably including, but not limited to, squaraine dyes (also known as squarylium dyes) and/or croconylium dyes (a cyanine based family of dyes). Such dyes are commercially available from Sigma-Aldrich Co. of St. Louis, Mo., and from Crysta-Lyn Chemical Co. of Binghamton, N.Y. These trapping dyes may be attached to graphene via covalent bonding, by surface modification, or merely through physical contact. Techniques are already known for encapsulating squarylium dyes into carbon nanotubes; see, e.g., the article by K. Yanagi, et. al., J Am Chem Soc. 129 (16):4992 (2007). Similarly, American Dye Source, Inc. of Baie D'Urfé, Quebec, Canada, offers its services of chemically attaching custom dyes to fullerenes. Carbon nanotubes and fullerenes are chemically similar to graphene, and these techniques may also be applied to attach squarylium dyes and/or croconylium dyes to graphene.

The graphene layer incorporated within layer 110 can be in the form of one or more discrete sheets of graphene, or in the form of graphene aerogels. The exciton trapping molecules of the trapping dyes can be attached to graphene as discrete molecules, or as chains of molecules, as optimized for maximum energy and electronic transfer.

Pigment layer 120 is shown in FIG. 1 lying just below exciton trapping layer 110. Pigment layer 120 is actually formed by two or more dye mat patches within the same pigment layer; within FIG. 1, four such dye mat patches are indicated by reference numerals 121, 122, 123, and 124. While four such dye mat patches are illustrated, it is preferred that there be at least two different dyes that are responsive to different portions of the light spectrum. Dye patches 121, 122, 123, and 124 each preferably include organic dyes, although inorganic dyes might also be useful. These dye patches serve the primary purpose of absorbing the light energy (photons) and transferring excited-state electrons, in the form of excitons, to the exciton trapping layer molecules in layer 110 thereabove. In the preferred embodiment, each different dye patch mat (121, 122, 123, 124) contains a different type of organic dye pigment, each responsive to different wavelengths of light. Preferably, such dye patches are selected so that, cumulatively, they cover the majority of the available light spectrum (from visible to near infrared). Alternatively, each dye pigment patch may include at least two or more dyes responsive to different wavelengths of light.

Organic dye mats 121, 122, 123, and 124 of FIG. 1 are preferably deposited in patches as a mat, either by spray techniques, e.g., ink jet printing, screen printing, liquid phase reactions, or vapor deposition, as appropriate. The physical arrangement of the dye pigment patches may be a rectangular array, a hexagonal array, or any other array that is most effective. The dyes used to form such pigment mats are chosen to maximize the absorption range, absorption spectrum overlap, and redox gradient across layers. Preferred organic dyes used to form such pigment mats include porphyrin pigments and/or carotene pigments, which closely mimic chlorophyll molecules in the photosynthetic analog in plants. Other suitable near-infrared dyes include phenylenediamines.

Dye pigment mats 121, 122, 123, and 124 are preferably arranged in such a way as to leave spaces between adjacent pigment mats. Silicone moieties are preferably grafted, or dispersed, in pigment layer 120, and optionally, in the other layers, and later cured, in order to form a rubbery network that provides shock absorption in the finished solar cell 101. Also, this rubbery network will prevent slippage or creep in the active layer when the cell is used in a vertical position. Ladder photoactive semiconductor polymers, such as pentacene, can also be used in place of, or in conjunction with, organic pigment dyes to form the pigment mats.

The exciton trapping molecule-graphene combination used to form layer 110 may also, if desired, be provided within the spaces between the adjacent pigment mats of layer 120 to maximize the surface area of contact for effective exciton trapping. In this regard, the same material used to form layer 110 is deposited into the spaces between the pre-cured, or semi-cured, pigment layer 120, as a liquid with appropriate viscosity, to fill, and level out, the spaces between mats 121, 122, 123, and 124. The structure of pigment layer 120 is then cured, or partially cured, in preparation for the attachment thereto of layer 110 (and the transparent electrode layer 100).

It should be appreciated that exciton trapping layer 110 and pigment layer 120 may be as thin as 100 nm or less; the thickness of such layers is optimized for maximum electron transfer, subject to the limits of the deposition techniques employed to form such layers. Layers 110 and 120 may be built up by methods that include, but are not limited to, spray techniques, e.g ink jet, screen printing, gravure printing, repetitive dip coating (into solutions of each layer's component species and subsequent drying) and liquid phase reactions, chemical or physical vapor deposition, as appropriate. Each layer is cured, either fully or partially, using thermal or UV curing techniques to adhere it unto the underlying layer, before the next layer above it is deposited and then cured. This helps prevent interpenetration of layers.

If desired, a block copolymer (not shown in FIG. 1), containing the dyes present in both layers 110 and 120, may be deposited between layers 110 and 120 to further facilitate electron transfer, and minimize interfacial resistance, between layers 110 and 120. These block copolymers can be deposited in a similar manner as the layers above and below them. Similar compatibilizers can be used between all other adjacent contacting layers, as needed, to improve adherence and electron/energy transfer. Once again, silicone moieties may be grafted, or dispersed, in this intermediate block copolymer layer, if desired, and later cured, to provide shock absorption and physical stability in the final solar cell.

Referring again to FIG. 1, anionic polyelectrolyte layer 130 is disposed adjacent to, and below, pigment layer 120, and serves to supply electrons to dye pigment patches 121, 122, 123, and 124. The polyelectrolytes serve as carriers of excess electrons from a metallic backing electrode 140 to the dyes in pigment layer 120. While any appropriate anionic polyelectrolytes may be selected, the preferred embodiment uses polyphosphazene plus liquid electrolyte or ionic liquids in liquid or gel form. Iodide ions, or other ionic materials, may also be incorporated to facilitate electron transfer. Polyphophazene custom formulations and membranes can be procured through Technically, Incorporated of Woburn, Massacusetts.

The anionic polyelectrolyte must be easily oxidized by the dyes in pigment layer 120 due to redox potential gradient. Layer 130 may be rendered acidic, if desired, to provide sacrificial electron donors. Electron carriers such as quaternary ammonium, barium or calcium halides, ionic liquids, salts, or imidazoles, may be incorporated in layer 130 to facilitate electron transfer. Specialty quarternary ammonium salts are commercially available from Sachem Inc. of Austin, Tex.

Still referring to FIG. 1, backing electrode, or bottom substrate, 140 is preferably formed of metalized polymer sheets, or metal sheets, such as aluminum or copper adhered to polycarbonate/polyimides. In the case of metalized polymer sheets, metallization can be achieved by depositing a suitable conductor into grooves on the surface of the polymer sheet, or through holes in a polymer film. Bottom substrates for solar cell applications are available commercially from Henkel Corporation in collaboration with DuPont. Also, custom metalized films can be procured through Mirwec Film Inc. of Bloomington, Ind., or AZ Coat Inc. of Scottsdale, Ariz.

The function of backing electrode 140 is to return electrons from the external circuit back to solar cell 101, and to reduce the anionic polyelectrolyte layer 130 thereabove. If desired, the surface of backing electrode 140 can be roughened to increase its surface area, though layer 130 may be as thin as 100 nm or less; accordingly, dimensional control over roughness, porosity and thickness of backing electrode 140 may be necessary. If desired, an adhesion/electron transfer promoting interfacial layer may be provided on the upper surface of backing electrode 140.

If desired, backing electrode 140 can be purchased from printed circuit board fabricating companies as an “off-the-shelf” item, with copper conductive lines already adhered to the surface, and copper through-hole vias already plated through the polymer film. Typical processing for making such pc boards involves copper deposition on the polymer film, pattern development, etching, and stripping off excess copper. Alternatively, screen-printed silver conductive lines can be adhered to the substrate of backing electrode 140.

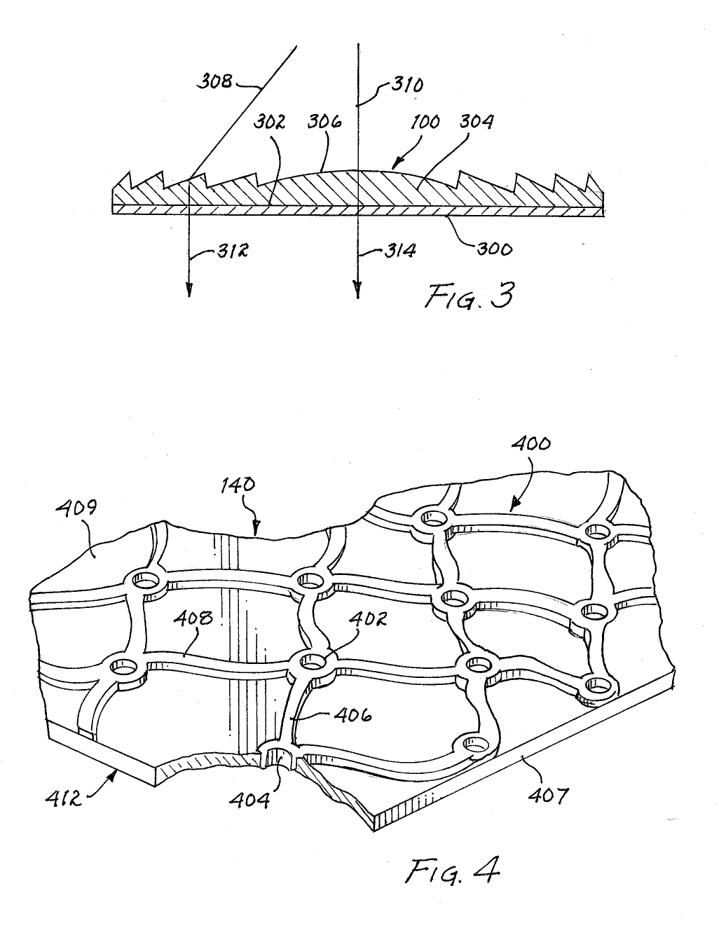

As shown in FIG. 4, in the preferred embodiment of the invention, backing electrode 140 includes a honeycomb pattern of conductive lines 400 that are formed upon upper surface 409 of polymer substrate 407. Metalized vias 402 and 404 are provided at the intersection of conductive lines 406 and 408, such vias extending downwardly through holes in polymer substrate 407 to the underside 412 of backing electrode 140. The metal extending downwardly through such vias is “plated-through” such holes to form electrically conductive paths to the underside 412 of backing electrode 140. The lower ends of such vias may each be electrically coupled to a buss for connection to an external circuit. Alternatively, the entire underside 412 of substrate 407 may be plated with metal to provide the cathode terminal of the solar cell.

As shown in FIG. 4, the honeycomb pattern of conductive traces 400 formed upon upper surface 409 of polymer substrate 407 have a thickness, whereby the upper surfaces of such conductive traces is higher than upper surface 409. Anionic polyelectrolyte layer 130 (see FIG. 1) may be deposited directly upon upper surface 409, allowing the anionic polyelectrolyte to extend over and between conductive traces 400.

Backing electrode 140 and anionic polyelectrolyte layer 130 may be assembled separately from layers 100, 110 and 120, and then both stacks of layers can be sandwiched, or adhered together, just after “activation” of polyelectrolyte layer 130 by either the ionic liquid or the liquid electrolyte, assuming that polyphosphazene is being used. Preferably, an appropriate encapsulant or sealant (not shown) is used along the outer perimeter of the backing electrode 140 and the upper transparent electrode sheet 100, to form a sealing bond. No dyes or graphene is required within this sealant contact area. As already noted above, layer 120 preferably includes a silicone, or rubbery, species which, when cured, provides a shock absorption effect.

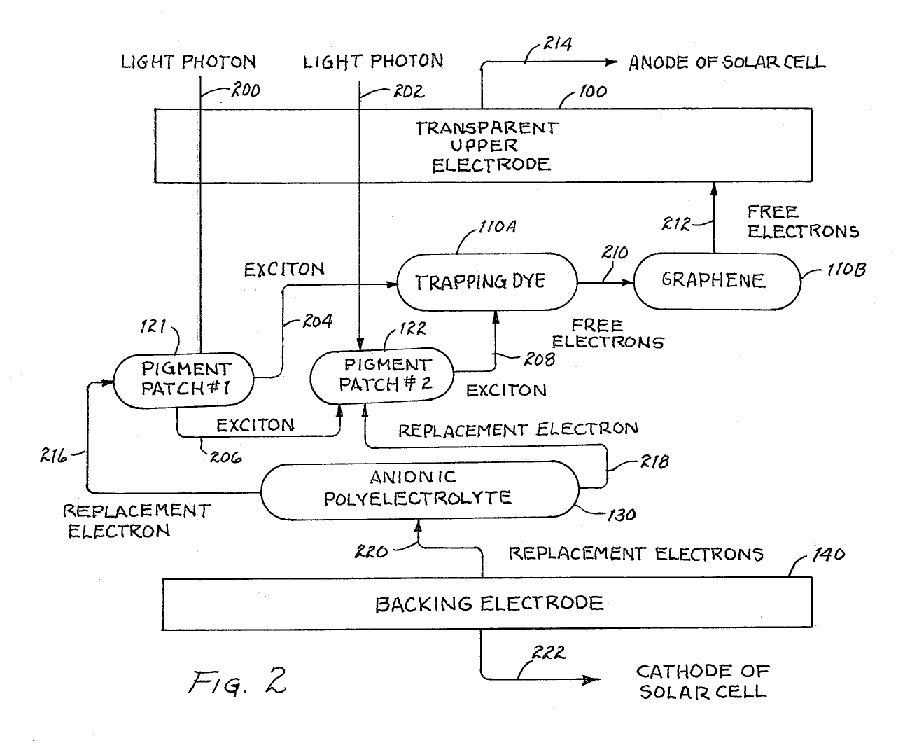

The functions of the various components of the solar cell shown in FIG. 1 are schematically illustrated in FIG. 2. Light photons 200 and 202 each pass through transparent upper electrode 100. Light photon 200 strikes pigment patch #1 (e.g., dye patch 121 of FIG. 1), and light photon 202 strikes pigment patch #2 (e.g., dye patch 122 of FIG. 1). Patch 121 absorbs photon 200 and emits first and second excitons, represented by arrows 204 and 206. Exciton 204 is transmitted to trapping dye 110A in the exciton trapping layer 110. Patch 122 absorbs photon 202 and emits exciton 208, which is likewise transmitted to trapping dye 110A in exciton trapping layer 110. Exciton 206 is absorbed by patch 122, which may independently cause patch 122 to emit excitons, like exciton 208. In this latter case, patch 121 is regarded as a donor dye, and patch 122 is regarded as an acceptor dye. Patch 121 “donates” exciton 206 to patch 122, and patch 122 “accepts” such exciton for emitting a further exciton that can be trapped by trapping dye 110A.

Within trapping dye 110A, trapped excitons are stripped of their excited free electrons, which are, in turn, readily conducted by graphene portion 110B of exciton trapping layer 110, as indicated by arrow 210 in FIG. 2. Once such free electrons reach graphene portion 110B, they are efficiently conducted to transparent upper electrode 100, as designated by arrow 212 in FIG. 2. The transparent upper electrode 100 serves as the anode of the solar cell, as indicated by arrow 214.

Still referring to FIG. 2, patch 121 and patch 122 have a net loss of electrons as excitons 204, 206, and 208 are transmitted. Replacement electrons 216 and 218 are conducted to patches 121 and 122, respectively, by the anionic polyelectrolyte 130. In turn, backing electrode 140 supplied replacement electrons to anionic polyelectrolyte 130, as indicated by arrow 220. Backing electrode 140 is electrically coupled to the cathode of the solar cell as indicated by arrow 222, completing the electrical circuit of electron flow through the solar cell.

The terminal output voltage of solar cell 101 is dependent on light irradiation, temperature and load conditions. The magnitude of the electrical voltage generated thereby increases with increased illumination, so there is never one specific voltage. The solar cell 101 described above may be used in standard solar cell modules of the type mounted on roofs of homes, on public streetlights, and on other sun-exposed surfaces, like covered parking spaces. Such solar cells can also be used on roofs of cars, incorporated into building glass, embedded into carry-cases or covers for mobile computing/communication devices (laptops, tablets, smartphones etc) for recharging, off-grid remote electrification, consumer electronic devices used indoors and outdoors, picture frame-like fixtures, tents and camping trailers and recreational vehicles, and adapted for other usage that may emerge in future. Such solar cells may be provided in the form of sheets that can be adhered to, or incorporated within, sun-, or light-, facing surfaces. The described solar cell can also form the energy generating component of a system that also includes batteries or supercapacitors for temporary power storage while light is available, and later discharge such power when light is not available, e.g., at night.

Those skilled in the art will now appreciate that a relatively inexpensive solar cell has been described which is believed to provide improved sunlight conversion efficiency. The improved solar cell does not require a semiconductor substrate, and is relatively easy to manufacture using known manufacturing techniques. The describe solar cell is adapted to capture a large portion of the impinging light for conversion into electricity. The improved method of trapping excitons produced by the dyes in the pigment layer ensures rapid electron transfer, and a charge-separated state sufficiently low in energy, to prevent back transfer of excitation energy, and minimizes recombination losses. Further, the concept of arranging donor and acceptor pigments adjacent one another further maximizes efficiency of electron transfer and charge separation.

While the present invention has been described with respect to preferred embodiments thereof, such description is for illustrative purposes only, and is not to be construed as limiting the scope of the invention. Various modifications and changes may be made to the described embodiments by those skilled in the art without departing from the true spirit and scope of the invention as defined by the appended claims.

I claim:

1. A solar cell comprising in combination:
a. a transparent upper electrode for conducting electrodes and for allowing incoming photons of light to pass therethrough;
b. an exciton trapping region disposed proximate to the transparent upper electrode, the exciton trapping region serving to conduct trapped electrons to the transparent electrode, the exciton trapping region including graphene and a first dye;
c. a pigment layer coupled to the exciton trapping region, the pigment layer absorbing photons of light within a first wavelength spectrum and emitting excitons in response thereto;
d. the first dye in the exciton trapping region serving to trap excitons emitted by the pigment layer and supplying freed electrons to the transparent upper electrode in response thereto; and
e. a backing electrode electrically coupled to the pigment layer for transporting electrons to the pigment layer to replenish electrons conducted by the transparent upper electrode.

2. The solar cell recited by claim 1 wherein the pigment layer includes at least a second dye different from the first dye included in the exciton trapping region.

3. The solar cell recited by claim 1 including a light concentrating cover sheet overlying the transparent upper electrode to focus incoming light toward the pigment layer.

4. The solar cell recited by claim 3 wherein the light concentrating sheet is made of a transparent polymer.

5. The solar cell recited by claim 3 wherein the light concentrating sheet is made of glass.

6. The solar cell recited by claim 1 wherein:
a. the first dye in the exciton trapping region traps excitons that are within a predetermined exciton wavelength spectrum; and
a. the pigment layer emits excitons within the predetermined exciton wavelength spectrum.

7. The solar cell recited by claim 1 wherein the exciton trapping region and the pigment layer are joined together to form a combined layer of material.

8. The solar cell recited by claim 1 wherein the transparent upper electrode includes:
a. a transparent sheet of material having upper and lower opposing surfaces, the lower surface being disposed proximate to the graphene layer; and
b. a transparent, electrically-conductive layer formed upon the lower surface of the transparent sheet.

9. The solar cell recited by claim 8 wherein the transparent sheet is made of polymer.

10. The solar cell recited by claim 8 wherein the transparent sheet is made of glass.

11. The solar cell recited by claim 8 wherein the upper surface of the transparent sheet includes at least one lens to focus incoming light downwardly through the transparent sheet toward the pigment layer.

12. The solar cell recited by claim 11 wherein the at least one lens is a Fresnel lens to intercept and transmit incident light from a wide array of angles.

13. The solar cell recited by claim 12 wherein the transparent sheet of material is a plastic Fresnel lens sheet.

14. The solar cell recited by claim 8 wherein the transparent electrically conductive layer is formed of a thin film of indium tungsten oxide (ITO).

15. The solar cell recited by claim 1 wherein the pigment layer includes at least two distinct patches of dyes wherein:
a. the first patch includes a second dye different from the first dye included in the exciton trapping region, the second dye absorbing photons of light within one portion of the first wavelength spectrum and emitting excitons in response thereto; and
b. the second patch includes a third dye different from the first dye included in the exciton trapping region, and different from the second dye, the third dye absorbing photons of light within a second portion of the first wavelength spectrum and emitting excitons in response thereto.

16. The solar cell recited by claim 15 wherein the second and third dyes are selected from the group of pigments consisting of porphyrin pigments, carotene pigments, and phenylenediamines.

17. The solar cell recited by claim 16 wherein the first and second patches are separated from each other by a space, and wherein a combination of graphene and the first dye is provided within such space.

18. The solar cell recited by claim 1 including silicone moieties to form a rubbery network.

19. The solar cell recited by claim 1 including a photoactive semiconductor polymer within the pigment layer.

20. The solar cell recited by claim 19 wherein the photoactive semiconductor polymer is pentacene.

21. The solar cell recited by claim 1 wherein the first dye includes squaraine dyes.

22. The solar cell recited by claim 1 wherein the first dye includes croconylium dyes.

23. The solar cell recited by claim 1 wherein the backing electrode is formed as a metalized polymer sheet.

24. The solar cell recited by claim 1 wherein the backing electrode is formed as a metal sheet.

25. The solar cell recited by claim 1 further including an anionic polyelectrolyte between the backing electrode and the pigment layer to transfer electrons from backing electrode to the pigment layer.

26. The solar cell recited by claim 25 wherein the anionic polyelectrolyte is acidic to provide sacrificial electron donors.

27. The solar cell recited by claim 25 wherein the anionic polyelectrolyte includes electron carriers selected from the group consisting of quaternary ammonium, barium halides, calcium halides, salts, ionic liquids, and imidazoles.

28. The solar cell recited by claim 25 wherein the anionic polyelectrolyte includes polyphosphazene in liquid form.

29. The solar cell recited by claim 25 wherein the anionic polyelectrolyte includes polyphosphazene in gel form.

30. The solar cell recited by claim 1 wherein:
a. the transparent upper electrode includes a peripheral edge surrounding the transparent upper electrode;
b. the backing electrode includes a peripheral edge surrounding the backing electrode;
c. the peripheral edges of the transparent upper electrode and the backing electrode being generally aligned with each other; and
d. the solar cell further includes a sealant formed over and around the peripheral edges of the transparent upper electrode and the backing electrode to encapsulate the solar cell.

31. A method of improving the efficiency of dye-sensitive solar cells, the dye-sensitive solar cell including a first light absorbing dye to absorb photons of light, and an upper translucent electrode in proximity to the first light absorbing dye for conducting electrons freed by the first light absorbing dye,
the improvement comprising the steps of:
a. providing a region of graphene molecules proximate to the first light absorbing dye;
b. adhering at least one trapping dye to the graphene molecules for trapping excitons emitted by the first light absorbing dye; and
c. transmitting freed electrons from the excitons trapped by the trapping dye to the graphene; and
d. transmitting such freed electrons from the graphene to the upper translucent electrode.

32. The method recited by claim 31 including the further steps of:
e. providing a second light absorbing dye proximate to the region of graphene molecules, and proximate the first light absorbing dye, the second light absorbing dye being different from the first light absorbing dye;
f. transmitting excitons emitted by the first light absorbing dye to the second light absorbing dye for causing the second light absorbing dye to emit a second round of excitons;
g. using the trapping dye to trap the second round of excitons emitted by the second light absorbing dye.
